(19) United States
(12) Patent Application Publication
(10) Pub. No.: US 2026/0123346 A1
(43) Pub. Date: Apr. 30, 2026

(54) METHOD AND APPARATUS FOR TEMPORARILY BONDING AND DEBONDING ELECTRONICS STRUCTURES RELATIVE TO CARRIER

(71) Applicant: PulseForge, Inc., Austin, TX (US)

(72) Inventors: Vikram Shreeshail Turkani, Austin, TX (US); Vahid Akhavan Attar, Austin, TX (US); Kurt A. Schroder, Coupland, TX (US)

(21) Appl. No.: 19/368,873

(22) Filed: Oct. 24, 2025

Related U.S. Application Data
(60) Provisional application No. 63/711,638, filed on Oct. 24, 2024.

(51) Int. Cl. H01L 21/683

(52) U.S. Cl. CPC H10P 72/74; H10P 72/7412; H10P 72/744

(57) ABSTRACT

A temporary stack for temporarily carrying an electronics structure for processing includes a reusable carrier structure and an electronics structure carried on the carrier structure. A bonding layer temporarily bonds the electronics structure to the carrier structure. The carrier structure includes a heat-generating layer configured to generate debonding heat for weakening the bonding layer. The bonding layer comprises at least one adhesive material. A method of debonding the temporary stack includes placing the stack in operative engagement with a source of debonding energy to generate debonding heat.

### CROSS-REFERENCE TO RELATED APPLICATIONS

This application claims the benefit of U.S. Provisional Application No. 63/711,638, filed Oct. 24, 2024, which is hereby incorporated herein by reference in its entirety.

### FIELD

The present disclosure generally relates to electronics device manufacturing, and more particularly equipment and methods that involve temporarily bonding an electronics structure to a carrier for processing.

### BACKGROUND

The present disclosure is directed to apparatuses and methods for temporary bonding and debonding (TBDB), which can be employed to affix fragile materials (e.g., electronics structures) to a maneuverable carrier to facilitate the processing of electronics structures such as electronics devices (e.g., small-scale electronics components, such as epoxy molding compound packaging, integrated circuit packaging, power or MOS devices, microelectromechanical systems (MEMS), multijunction or tandem solar cells, two-dimensional materials, battery materials, displays, wafers, panels, etc.) in manufacturing settings.

### SUMMARY

In one aspect, a temporary stack for temporarily carrying an electronics structure for processing comprises a reusable carrier structure. The reusable carrier structure comprises a carrier body and a heat-generating layer carried on the carrier body. The carrier structure defines a bonding surface on a first side of the carrier structure. The temporary stack additionally comprises an electronics structure temporarily carried by the carrier structure on the first side. The temporary stack further comprises a bonding layer configured to temporarily bond the electronics structure to the bonding surface. The bonding layer comprises at least one promotional material and at least one adhesive material. The heat-generating layer is configured to generate a debonding heat upon exposure to one or more pulses of debonding energy and transfer the debonding heat to the bonding layer. The at least one promotional material and the at least one adhesive material are configured to react to form a foam byproduct when the at least one promotional material is exposed to the debonding heat.

In another aspect, a method of processing an electronics structure comprises providing a temporary stack. The temporary stack comprises a reusable carrier structure. The reusable carrier structure comprises a carrier body and a heat-generating layer carried by the carrier body on a first side of the carrier structure. The carrier structure defines a bonding surface on the first side. The temporary stack additionally comprises an electronics structure temporarily carried by the carrier structure on the first side. The temporary stack further comprises a bonding layer configured to temporarily bond the electronics structure to the bonding surface. The bonding layer comprises at least one adhesive material and at least one gas-generating material. Each one of the at least one gas-generating material has a respective gasification temperature that is lower than a respective gasification temperature of each one of the at least one adhesive material. The method additionally comprises exposing the heat-generating layer to one or more pulses of debonding energy that cause the at least one gas-generating material to generate gas. The method then comprises separating the electronics structure from the carrier structure after the gas is generated.

In yet another aspect, a temporary stack for temporarily carrying an electronics structure for processing comprises a reusable carrier structure. The reusable carrier structure comprises a carrier body and a heat-generating layer carried on the carrier body on a first side of the carrier structure. The carrier structure defines a bonding surface on the first side. The temporary stack also comprises an electronics structure temporarily carried by the carrier structure on the first side. The temporary stack further comprises a bonding layer configured to temporarily bond the electronics structure to the bonding surface. The heat-generating layer is configured to generate a debonding heat upon exposure to one or more pulses of debonding energy. The bonding layer comprises at least one adhesive material and at least one gas-generating material configured to generate gas upon exposure to the debonding heat. The temporary stack is configured to transfer heat across the bonding surface with a substantially uniform energy distribution.

Other objects and features will be in part apparent and in part pointed out hereinafter.

### BRIEF DESCRIPTION OF THE DRAWINGS

FIG. 1A is a diagram of a carrier-electronics structure stack in accordance with an example temporary bonding and debonding method;

FIG. 1B is a diagram of the carrier-electronics structure stack being exposed to light from a light source in accordance with the example temporary bonding and debonding method;

FIG. 1C is a diagram of the electronics structure separated from the carrier in accordance with the example temporary bonding and debonding method;

FIG. 2A is a diagram of a carrier-electronics structure stack in accordance with a second example temporary bonding and debonding method;

FIGS. 2B and 2C are diagrams of the carrier-electronics structure stack being exposed to light from a light source in accordance with the second example temporary bonding and debonding method;

FIG. 2D is a diagram of the electronics structure separated from the carrier in accordance with the second example temporary bonding and debonding method;

FIG. 3A is a diagram of a carrier-electronics structure stack in accordance with a third example temporary bonding and debonding method;

FIG. 3B is a diagram of the carrier-electronics structure stack being exposed to light from a light source in accordance with the third example temporary bonding and debonding method;

FIG. 3C is a diagram of the electronics structure separated from the carrier in accordance with the third example temporary bonding and debonding method;

FIG. 4A is a diagram of a carrier-electronics structure stack in accordance with a fourth example temporary bonding and debonding method; and

FIG. 4B is a diagram of the carrier-electronics structure stack being exposed to electrical current from an electricity source in accordance with the fourth example temporary bonding and debonding method.

Corresponding reference characters indicate corresponding parts throughout the drawings.

### DETAILED DESCRIPTION

The present disclosure relates to varieties of carriers (broadly, “carrier structures”) used in TBDB and a bonded stack that includes such a carrier that carries an electronics structure so processing operations can be performed while the electronics structure is temporarily carried by the carrier. In the TBDB process, a bonding layer comprising a temporary adhesive material is used to temporarily secure a functional material (e.g., electronics structure) to a carrier (e.g., a rigid dummy substrate) for processing. After processing, lasers, heat, chemicals, or mechanical methods may be employed to separate the processed device from its respective carrier by weakening (e.g., damaging) an interface between the bonding layer and the processed device or between the adhesive and the carrier.

In some configurations, carriers can comprise a heat-generating layer (broadly, a thermally active layer) configured to generate heat when energy is emitted from an energy source in order to cause thermal debonding. In the field of semiconductor wafer debonding, methods using a flashlamp (e.g., broadband or incoherent light source) as a debonding light source to generate heat can be referred to as photonic debonding. Examples of apparatuses and systems for performing temporary bonding and debonding using photonic debonding equipment are disclosed in U.S. Pat. No. 11,996,384, and U.S. Patent Application Publications No. 2024/0321816, 2024/0297144, and 2025/0022838, the contents of which are hereby incorporated herein by reference in their entirety. A debonding process using a laser (e.g., coherent light source) as a debonding light source to generate heat can be referred to as laser debonding. For example, a continuous wave laser can be pulsed to generate controlled amounts of heat for the debonding. In configurations in which photonic or laser debonding is employed, a light-absorbing layer (LAL) can be carried on the carrier to function as a heat-generating layer that absorbs light to generate heat. Alternatively, as disclosed in U.S. Pat. No. 11,358,381 and U.S. Patent Application Publication No. 2022/0306177, the contents of which are hereby incorporated herein by reference in their entirety, a light-absorbing material can be added to the bonding layer to generate heat directly in the bonding layer. Other varieties of heat-generating layers may be used, such as an electrically conductive layer (ECL) that generates heat as electrical current is directed through the ECL from an electrical current generating source.

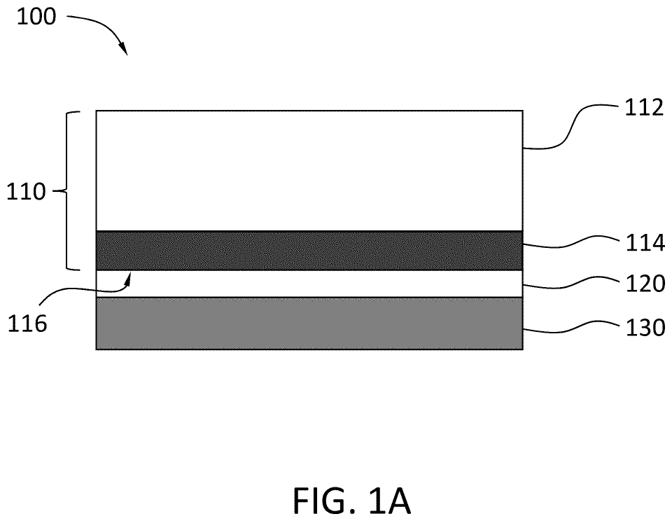

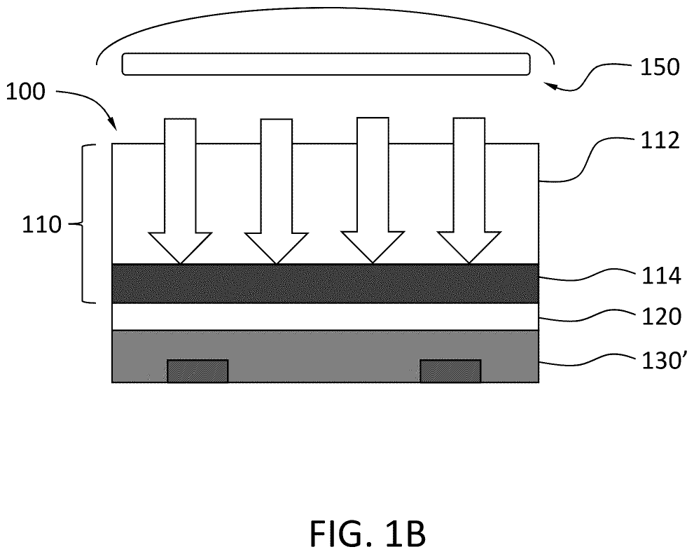

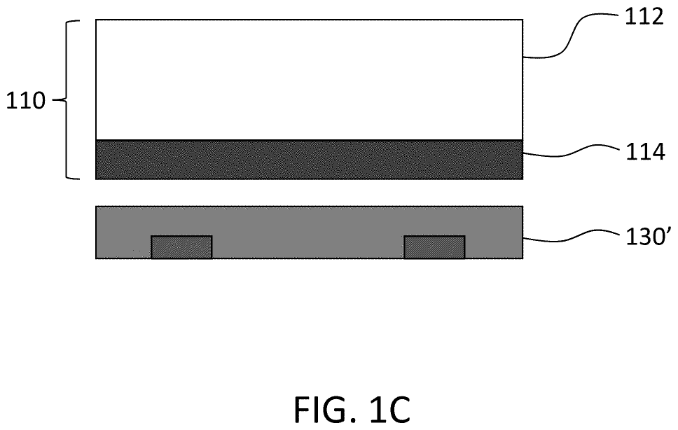

Referring to FIGS. 1A-IC, an example of a TBDB process using a reusable carrier structure, an electronics structure, and a bonding layer configured to decompose substantially entirely during a debonding cycle is shown. In accordance with this example, a temporary stack for temporarily carrying an electronics structure for processing is shown generally as reference number 100 in FIG. 1A. The stack 100 includes a reusable carrier structure 110, a bonding layer 120, and an electronics structure 130. The reusable carrier structure 110 includes a carrier body 112 and an LAL 114 (broadly, a heat-generating layer) located on one side (e.g., a first side) of the carrier structure. An exposed surface of the LAL 114 defines a bonding surface 116 of the carrier structure 110. It will be appreciated that, in various other examples, other layers of material (e.g., a protective passivation layer and/or a layer comprising a low-surface-tension material, not shown) may be located outboard of the LAL 114 to define the bonding surface 116 without departing from the scope of the present disclosure. The bonding layer 120 is configured to temporarily affix one side of the electronics structure 130 (e.g., a non-working side of the electronics structure) to the bonding surface 116 so the carrier structure 110 can be used to temporarily carry the electronics structure for one or more processing operations.

In the present example, the carrier structure 110 is configured for photonic or laser debonding. It is contemplated that the carrier body 112 can comprise a variety of substantially rigid, thermally stable materials that are substantially transmissive in a debonding light wavelength range (e.g., some or all of the IR-NIR-visible-UV light spectrum) to which the LAL 114 is substantially absorptive. In this respect, it will be appreciated that the carrier body 112 and the LAL 114 are preferably matched for optimal energy efficiency relative to a debonding light source such as the light source 150 discussed below in connection with FIG. 1B. The carrier body 112 can comprise rigid materials such as sapphire, quartz, and glass which generally exhibit transmissivity in broadband wavelength ranges and respectively demonstrate varying advantages in durability and/or economy. The carrier body 112 generally has a thickness ranging from tens of microns (e.g., around 50 microns) to hundreds of microns (e.g., around 200 microns to around 500 microns). Depending on various parameters including maximum processing temperature, durability, desired debonding wavelength range, thermal efficiency, controlled heat transfer, coefficient of thermal expansion (CTE), and any variety of other considerations, the LAL 114 can comprise a variety of different materials, including carbon-based materials (e.g., amorphous carbon, graphite), metal oxides (e.g., tungsten oxide, titanium oxide), metals and metal alloys (e.g., iron, aluminum, copper, nickel, gold, silver, tin, cobalt, manganese, chromium, germanium, palladium, platinum, rhodium, silicon, tungsten, zinc, titanium, and tellurium), or organic dyes. In further aspects, the LAL 114 can include plasmonic nanoparticles with resonance in particular light wavelength ranges. Depending on the material or materials used in the LAL 114, the LAL can vary in thickness from around 10 nm to around 5 microns.

As discussed below in connection with FIGS. 1B-1C, in the present example, the bonding layer 120 comprises at least one adhesive material and at least one energy-generating material configured to generate localized energy in regions of the bonding layer away from the bonding surface 116 when the LAL 114 absorbs light in the debonding light wavelength range. The bonding layer 120 is configured to decompose substantially entirely as a result of the heat generated by the LAL 114 and the at least one energy-generating material located in the bonding layer. It is contemplated that the LAL 114 can be configured to absorb a pulse of debonding light from light source 150 to generate debonding heat that is transferred through the bonding surface 116 and into nearby portions of the bonding layer 120. The at least one energy-generating material in the portions of the bonding layer 120 near the bonding surface 116 are stimulated by the transferred heat and actively react to generate additional energy. The additional energy generated by the energy-generating materials produces heat and may additionally produce physical energy through forceful gas generation. The heat produced by the energy-generating materials causes additional heat transfer through the bonding layer (e.g., away from the bonding surface 116), which causes additional portions of the at least one energy-generating material to react away from the bonding surface 116 (e.g., in a chain reaction). Additionally, the energy produced by the at least one energy-generating material causes the at least one adhesive material in the bonding layer 120 to decompose (e.g., by vaporizing, melting, or otherwise lose form). The reactions and corresponding generation of energy continue until substantially all of the bonding layer 120 is heated and decomposed.

The at least one adhesive material in the bonding layer 120 can, for example, include: thermally reactive adhesive materials that degrade or soften (broadly, weaken) upon exposure to heat (e.g., polyurethane), photo-curable adhesives configured to cure upon exposure to UV light and to weaken after exposure to specified temperatures (e.g., 3M™ Liquid UV-Curable Adhesive LC-3200), solders configured to melt at relatively low temperatures (e.g., solders comprising indium or bismuth), or organic polymers configured to release gas when exposed to heat and/or stimulating light (e.g., polyimides, acrylics). The at least one energy-generating material can include a combination of heat-generating and gas-generating materials, for example: sublimation dyes configured to vaporize when exposed to threshold temperatures, self-reacting materials (e.g., nitrocellulose, cordite, sodium nitrate, ammonium nitrate, chlorates, perchlorates, and other propellants or low-order explosives), and binary reactive materials (e.g., thermitic metal-metal oxide pairs, metal-fluoride pairs, intermetallics, and other reducer-oxidizer pairs that rapidly generate gas). It is contemplated that the at least one adhesive material and the at least one energy-generating material can be arranged in discrete sub-layers in the bonding layer 120 or in interspersed formations without departing from the scope of the present disclosure.

In use, it will be appreciated that the electronics structure 130 can be bonded to the carrier structure 110 by applying the bonding layer 120 to bonding surface 116 and aligning the electronics structure with the carrier structure and bonding layer. The electronics structure is brought in contact with the bonding layer 120, and bonding is completed by thermocompression bonding and/or UV curing (e.g., at room temperature) to solidify bonding provided by the at least one adhesive material. After the bonding is complete, the bonded stack 100 may undergo post-bonding heat treatment. After the stack 100 is bonded, the electronics structure 130 can be processed in a variety of different ways, including without limitation: bonding with semiconductor substrates, displays, photovoltaic devices, or storage devices, and/or fabrication via processes such as lithography, etching, deposition, and other varieties of thermal, chemical, or mechanical processes.

As can be seen in FIG. 1B, after processing is completed, the stack 100 carrying processed electronics structure 130′ can be debonded by placing the stack near a light source 150 (and/or moving the light source relative to the stack) to expose the carrier structure 110 to one or more pulses of debonding light generated by the light source. The stack 100 is positioned relative to the light source 150 so that the debonding light travels through a back side of the carrier body 112 (e.g., opposite the side the carrier structure 110 on which the bonding surface 116 is located) for absorption by the LAL 114. The light is absorbed by the LAL 114, resulting in heat generation in the LAL and heat transfer to the bonding layer 120. In the present example, the light source 150 comprises a flashlamp that is operable to flash multiple times according to one or more operating parameters for the flashlamp, such as pulse length, pulse interval, flash intensity, and/or other metrics based on these parameters. In the present example, the light source 150 provides beams of incoherent light having a beam width that is at least as wide as the carrier structure 110. The debonding light can have a broadband debonding light wavelength range spanning from around 200 nm to around 1,500 nm, though other debonding light wavelengths (e.g., monochromatic wavelengths) and/or wavelength ranges can be used without departing from the scope of the present disclosure. The pulses of debonding light from the light source 150 (broadly, debonding energy) generates heat in the LAL 114 that is transferred into the bonding layer 120. As shown in FIG. 1C, the heat transferred from the LAL 114 to the bonding layer 120 causes the bonding layer to decompose substantially entirely such that a minimal amount of the bonding layer 120 remains bonded to the processed electronics structure 130′ and/or the bonding surface 116 of the carrier structure 110.

In the present example, the decomposition of substantially the entire bonding layer 120 provides several functional advantages over other TBDB processes in which substantial amounts of material from the bonding layers remain on carrier structures and/or processed electronics structures following debonding. First, as can be seen in FIG. 1C, the vaporization facilitates a clean separation of the electronics substrate 130′ from the carrier structure 110 without a need for substantial mechanical force to overcome residual adhesive forces in a bonding layer that is only partially weakened or disintegrated. Reductions in mechanical force can increase energy efficiency of debonding systems and are especially beneficial for fragile or otherwise sensitive semiconductor or MEMS devices that are susceptible to substrate damage, yield loss, or other undesired effects resulting from mechanical stress during forceful separation. Additionally, the decomposition of substantially the entire bonding layer 120 facilitates post-TBDB cleaning procedures by reducing the amount of residue from the bonding layer. The reduction in material requiring rigorous cleaning can result in faster, more efficient, and less expensive and resource-intensive cleaning cycles. Moreover, when the light source 150 emits debonding light having a substantially uniform radiant exposure (in J/cm²) across all portions of the LAL 114, the LAL generates heat in a substantially uniform profile that provides for substantially uniform energy generation and decomposition in all regions of the bonding layer 120 and thereby reduces the likelihood of force imbalances that could occur when the energy generation or decomposition is only partial or occurs more aggressively in only some regions of the bonding layer.

It is contemplated that the equipment and methods described in the present example can be adapted and modified for application with a wide range of electronics devices to be processed in a manufacturing environment, and that a variety of materials can be used in suitable bonding layers without departing from the scope of the present disclosure. Additionally, although the light source 150 is described above as a flashlamp, it will be appreciated that other kinds of light sources, such as a continuous wave laser, can be used to provide other sources of pulsed energy without departing from the scope of the disclosure.

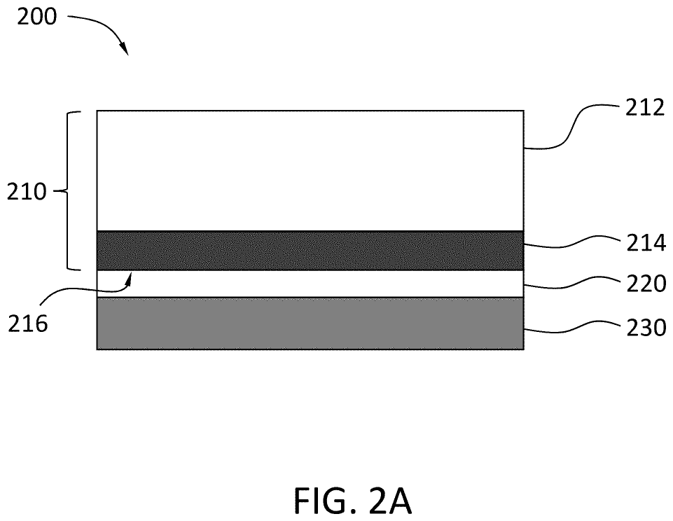

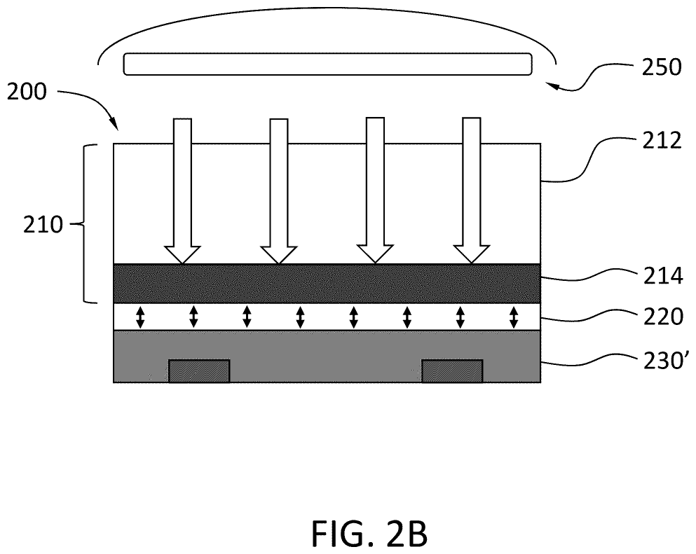

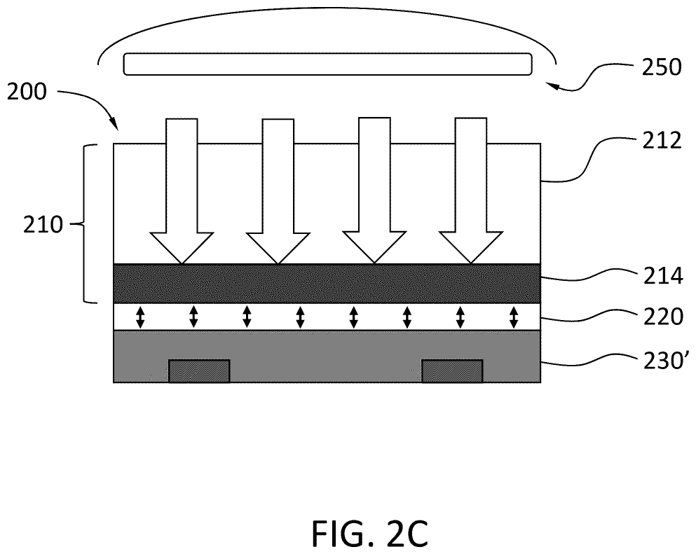

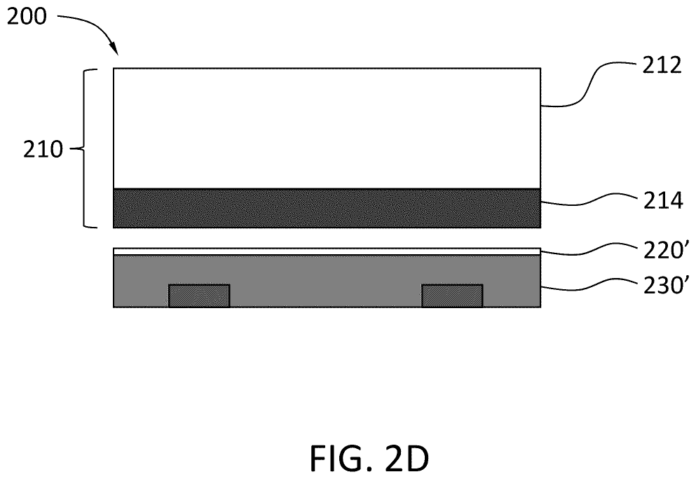

Now referring to FIGS. 2A-2D, an example of a TBDB process using a reusable carrier structure, an electronics structure, and a bonding layer configured to promote forceful gas generation during a debonding cycle is shown. In accordance with this example, a temporary stack for temporarily carrying an electronics structure for processing is shown generally as reference number 200 in FIG. 2A. The stack 200 includes a reusable carrier structure 210, a bonding layer 220, and an electronics structure 230. The reusable carrier structure 210 includes a carrier body 212 and an LAL 214 (broadly, a heat-generating layer) located on one side (e.g., a first side) of the carrier structure. An exposed surface of the LAL 214 defines a bonding surface 216 of the carrier structure 210. It will be appreciated that the reusable carrier structure 210 and the electronics structure 230 can have the same or similar structural characteristics as corresponding structures 110 and 130 discussed above in connection with FIGS. 1A-1C, and that other layers of material (e.g., a protective passivation layer and/or a layer comprising a low-surface-tension material, not shown) may be located outboard of the LAL 214 to define the bonding surface 216 without departing from the scope of the present disclosure. The bonding layer 220 is configured to temporarily affix one side of the electronics structure 230 (e.g., a non-working side of the electronics structure) to the bonding surface 216 so the carrier structure 210 can be used to temporarily carry the electronics structure for one or more processing operations.

In the present example, the bonding layer 220 comprises at least one adhesive material and at least one promotional material configured to provide or facilitate generation of gas. The at least one adhesive material of the bonding layer 220 provides a temporary bonding force to securely carry the electronics structure 230 on the carrier structure 210 for processing. The at least one adhesive material may be configured to weaken (e.g., decompose, detackify, or gasify) upon reaching a respective at least one debonding threshold temperature (e.g., a first debonding threshold temperature associated with a first adhesive material, a second debonding threshold temperature associated with a second adhesive material, etc.). Each one of the at least one adhesive material in the bonding layer 220 may have a respective gasification temperature at which the corresponding adhesive material gasifies. Each one of the at least one promotional material in the bonding layer 220 is configured to gasify or promote gasification of a different, gas-generating material in the bonding layer at a respective gasification temperature that is lower than the respective gasification temperature associated with one or more of the at least one adhesive material. The at least one promotional material can be selected to interact with the at least one adhesive material to facilitate a debonding cycle in which modulated pulses of light energy (broadly, debonding energy) are absorbed by the LAL 214 to heat the at least one promotional material and sequentially gasify (e.g., one-by-one) multiple different gas-generating materials in the bonding layer 220 and eventually weaken or gasify the at least one adhesive material in a controlled order based on the modulated pulses, as described in greater detail below.

Several examples of adhesive materials that can be included in the bonding layer 220 are: thermally reactive adhesives that degrade or soften (broadly, weaken) upon exposure to heat (e.g., epoxy or polyurethane), photo-curable adhesives configured to cure upon exposure to UV light and weaken under specific thermal conditions (e.g., 3M™ Liquid UV-Curable Adhesive LC-3200), solders configured to melt at low temperatures (e.g., comprising indium or bismuth), or organic polymers configured to release gas when exposed to heat and/or stimulating light (e.g., polyimides, acrylics).

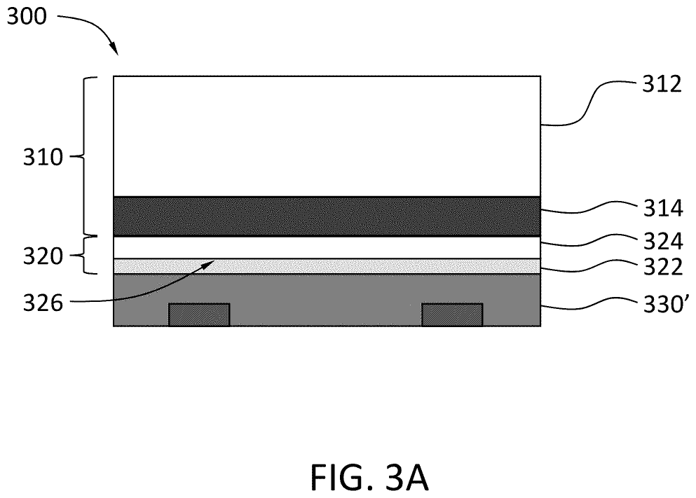

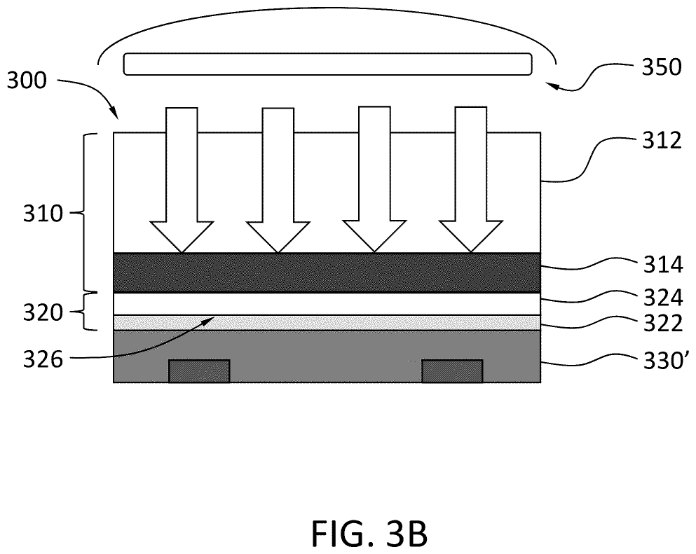

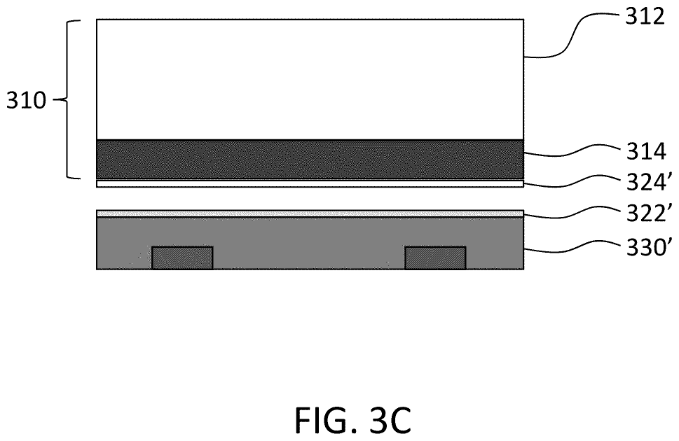

As non-limiting examples, the at least one promotional material that can be added with the at least one adhesive material in the bonding layer 220 may comprise: sublimation dyes configured to vaporize when exposed to threshold temperatures, self-reacting materials, binary reactive materials, or combinations of one or more of these materials or similar materials. The at least one promotional material can be mixed with other materials (e.g., the at least one adhesive material) to form a unitary bonding layer 220. Alternatively, as discussed below in connection with FIGS. 3A-3C, the promotional material may be formed as a discrete promotional material sub-layer that defines an interface with an adhesive sub-layer. Examples of self-reacting materials that can be used as promotional material include nitrocellulose, cordite, nitrates (e.g., sodium nitrate, ammonium nitrate), chlorates, perchlorates, and other propellants or low-order explosives. Self-reacting materials can be dissolved by solvents and spin-coated onto a surface (e.g., bonding surface 216) and/or combined with suitable adhesive materials and thermocompression bonded to form the bonding layer 220. Examples of binary reactive materials include thermitic metal-metal oxide pairs, metal-fluoride pairs (e.g., aluminum film coated with a fluoropolymer material like PTFE), intermetallics, and other reducer-oxidizer pairs that rapidly generate gas. In further aspects, the at least one promotional material can be configured to generate foam when stimulated with sufficient energy to react with one or more of the at least one adhesive material in the bonding layer 220.

As generally discussed below in connection with FIGS. 2B-2C, each of the at least one gas-generating material is selected to release gas at a respective gasification temperature that is lower than the respective gasification temperatures associated with the at least one adhesive material. Additionally, it will be appreciated that each gas-generating material may be selected to avoid premature activation from elevated processing temperatures while the electronics structure 230 undergoes general processing prior to a desired debonding stage.

Now referring to FIGS. 2B-2C, after processing is completed, the stack 200 carrying the processed electronics structure 230′ can be debonded by placing the stack near light source 250 (and/or moving the light source relative to the stack) to expose the carrier structure 210 to a plurality of pulses of debonding light generated by the light source. It will be appreciated that the light source 250 can have the same structure and operational characteristics of the light source 150 discussed above in connection with FIG. 1B. It is contemplated that the light source can be pulsed multiple times and that one or more operating parameters of the light source (e.g., pulse length, pulse interval, flash intensity, and/or other metrics based on these parameters) can be modulated between pulses to achieve several targeted threshold temperatures in short succession. For example, in FIG. 2B, the light source 250 is operated in accordance with a first set of operating parameters to emit a first pulse of debonding light (broadly, debonding energy) that is absorbed by the LAL 214 to generate sufficient heat to activate the promotional material to generate gas in the bonding layer 220. Depending on the composition of the promotional material, the promotional material may individually generate gas, or the promotional material may produce a local exothermic reaction that causes a different, gas-generating material to generate gas. It will be appreciated that the heat generated in response to the first pulse of debonding light is not sufficient to weaken or gasify the at least one adhesive material in the bonding layer 220.

The heat generated in response to the first pulse of debonding light is momentary and dissipates rapidly. Additionally, in the phase transitions in which the gas is generated, some thermal energy is effectively absorbed in the gas-generating reaction. The rapid heat dissipation from a single pulse of the debonding light may necessitate operating the light source 250 to emit several pulses of debonding light under the same or similar operating parameters as were used to produce the first pulse of debonding light, with each pulse generating sufficient heat to activate additional portions of the promotional material. The pulses can be repeated, for example, until substantially all of the promotional material in the bonding layer 220 has been activated. The gas generated by the gas-generating material can be used to provide a distributed force that counteracts the adhesive strength of the at least one adhesive material in the bonding layer 220 to facilitate separation of the processed electronics structure 230′ from the carrier body 210.

As can be seen in FIG. 2C, after the desired amount of gas is generated from pulsing debonding light from the light source 250 in accordance with the first set of operating parameters, one or more operating parameters of the debonding light source can be modulated (e.g., adjusted) to adjust the energy output of the light source (e.g., by manipulating intensity, duration, frequency, etc.). A second pulse of debonding light is emitted by the light source in accordance with the modulated operating parameters. The second pulse of debonding light generates a different amount of debonding energy (e.g., a greater amount of energy) than the first pulse of debonding light. The LAL 214 absorbs the energy from the second pulse of debonding light and generates sufficient heat to weaken the adhesive material in the bonding layer 220. The weakening of the adhesive material facilitates debonding when combined with the gas generated by the first pulse (or plurality of pulses) of debonding light discussed above in connection with FIG. 2B, which create an oppositional force that facilitates debonding. The steps described herein can therefore be used to reduce a maximum amount of energy needed to debond the processed electronics structure 230′ from the carrier structure 210 and/or to promote debonding with a reduction in external forces applied to the processed electronics structure and/or carrier structure. As generally shown in FIG. 2D, after the first and second pulses of debonding light (or pluralities of pulses) have been emitted, the processed electronics structure 230′ can be physically separated from the carrier structure 210. Any residual portions 220′ of the bonding layer can be cleaned off, e.g., using a cleaning solution.

When the light source 250 emits debonding light having a substantially uniform radiant exposure (in J/cm²) across all portions of the LAL 214, the LAL generates heat and transfers the heat across the bonding surface 216 in a substantially uniform profile that provides for substantially uniform gas generation in all regions of the bonding layer 220. The substantially uniform heating distribution reduces the likelihood of force imbalances that could occur when gas generation only occurs in some regions or is otherwise non-uniform. In this respect, the carrier structure 210 can be configured to provide a substantially uniform energy distribution that promotes balanced force distributions in the stack 200 during the debonding process.

It will be appreciated that the use of modulated pulses in the present example can provide several advantages to the TBDB process. For example, the use of modulated debonding pulses over time can mitigate spikes in heat transferred through the bonding layer 220 that could damage one or more components in the processed electronics structure 230′ if not distributed over time. The modulation of debonding pulses can additionally stagger the activation of gas-generating materials and/or the weakening of adhesive materials to avoid high-impact moments that could cause excessive physical stress in the electronics structure 230′. Although the activation of gas-generating materials is described in connection with FIG. 2B as a single step in accordance with a single set of operating parameters, it will further be appreciated that multiple gas-generating materials may be activated sequentially by providing modulated debonding pulses within the step (or repeating the step with modulated operating parameters) without departing from the scope of the disclosure.

As indicated above, one or more of the gas-generating materials in the bonding layer 220 may be configured to generate foam in the at least one adhesive material. It is contemplated that the generation of foam can facilitate debonding by creating physical gaps in portions of the bonding layer 220 and can facilitate cleaning the residual bonding layer portions 220′ by increasing a surface area of the residual material, allowing for increased exposure to solvent-based cleaning mediums. The improved physical debonding and cleaning can enhance the durability of the processed electronics structure 230′ and the reusability of the carrier structure 210 for additional TBDB cycles.

Now referring to FIGS. 3A-3C, another example of a TBDB process using a reusable carrier structure, an electronics structure, and a bonding layer configured to promote forceful gas generation during a debonding cycle is shown. In accordance with this example, a temporary stack for temporarily carrying an electronics structure for processing is shown generally as reference number 300 in FIG. 3A. The stack 300 includes a reusable carrier structure 310, a bonding layer 320, and an electronics structure 330. The reusable carrier structure 310 includes a carrier body 312 and an LAL 314 (broadly, a heat-generating layer) located on one side (e.g., a first side) of the carrier structure. An exposed surface of the LAL 314 defines a bonding surface 316 of the carrier structure 310. It will be appreciated that the reusable carrier structure 310 and the electronics structure 330 can have the same or similar structural characteristics as corresponding structures 110/210 and 130/230 discussed above in connection with FIGS. 1A-1C/2A-2D, respectively, and that other layers of material (e.g., a protective passivation layer and/or a layer comprising a low-surface-tension material, not shown) may be located outboard of the LAL 314 to define the bonding surface 316 without departing from the scope of the present disclosure. The bonding layer 320 is configured to temporarily affix one side of the electronics structure 330 (e.g., a non-working side of the electronics structure) to the bonding surface 316 so the carrier structure 310 can be used to temporarily carry the electronics structure for one or more processing operations.

In the present example, the bonding layer 320 comprises an adhesive sub-layer 322 and a promotional sub-layer 324 that define an interface 326 between the sub-layers. The adhesive sub-layer 322 includes at least one adhesive material that promotes the bonding of the electronics structure 330 to the carrier structure 310 to temporarily carry the electronics structure for processing. The promotional sub-layer 334 includes at least one promotional material configured to provide gas and/or facilitate generation of gas to weaken the bonding layer 320. As described in greater detail below, the weakening of the bonding layer 320 can be a result of force and/or heat produced by activating the at least one promotional material, resulting in physical separation in and/or vaporization of one or more of the at least one adhesive material near the interface 326, the generation of a foam byproduct on either side of the interface (e.g., byproduct layers 322′, 324′ described below in connection with FIG. 3C), or a combination thereof. Each one of the at least one promotional material in the promotional layer 324 is configured to gasify and/or promote gasification of one or more materials in the adhesive sub-layer 322 to generate the foam byproduct. It will be appreciated that when multiple different promotional materials are used, multiple modulated pulses can be used in accordance with the example described above in connection with FIGS. 2A-2D.

Several examples of adhesive materials that can generally be used in the adhesive sub-layer 322 include: thermally reactive adhesives that degrade or soften (broadly, weaken) upon exposure to heat (e.g., epoxy or polyurethane), photo-curable adhesives configured to cure upon exposure to UV light and weaken under specific thermal conditions (e.g., 3M™ Liquid UV-Curable Adhesive LC-3200), solders configured to melt at low temperatures (e.g., comprising indium or bismuth), or organic polymers configured to release gas when exposed to heat and/or stimulating light (e.g., polyimides, acrylics).

Several examples of promotional materials that can generally be used in the promotional sub-layer 324 include: sublimation dyes configured to vaporize when exposed to threshold temperatures, self-reacting materials, binary reactive materials, or combinations of one or more of these materials or similar materials. In the present example, the promotional material is provided in a discrete promotional material sub-layer that defines an interface with an adhesive sub-layer to form the entire bonding layer 320. However, it will be appreciated that the at least one promotional material can be mixed with other materials including the at least one adhesive material in a single bonding layer (e.g., bonding layer 220 discussed above in connection with FIGS. 2A-2D) without departing from the scope of the present disclosure. Examples of self-reacting materials that can be used as promotional material include nitrocellulose, cordite, nitrates (e.g., sodium nitrate, ammonium nitrate), chlorates, perchlorates, and other propellants or low-order explosives. Self-reacting materials can be dissolved by solvents and spin-coated onto a surface (e.g., bonding surface 316) and/or combined with suitable adhesive materials and thermocompression bonded to form the bonding layer 320. Examples of binary reactive materials include thermitic metal-metal oxide pairs, metal-fluoride pairs (e.g., aluminum film coated with a fluoropolymer material like PTFE), intermetallics, and other reducer-oxidizer pairs that rapidly generate gas.

In the present example, the promotional sub-layer 324 can include a self-reacting, gas-generating promotional material that is dissolved in a solvent. For instance, the self-reacting, gas-generating material can be nitrocellulose in an alcohol solvent that is spin-coated on the bonding surface 316 and dried to form a thin film. It will be appreciated that other materials and other solvents can be used without departing from the scope of the disclosure. The adhesive sub-layer 322 can have an adhesive material that is soluble in the same solvent as the self-reacting, gas-generating promotional material in the promotional layer 324. For example, the adhesive material can be the 3M™ Liquid UV-Curable Adhesive LC-3200. The adhesive material can be spin-coated on the promotional sub-layer 324. After the electronics structure 330 is aligned and placed on the adhesive sub-layer 322, the promotional sub-layer 324, the adhesive sub-layer, and the electronics structure are thermocompression bonded to form the temporarily bonded stack 300 so the electronics structure can be carried for processing.

As can be seen in FIG. 3B, after processing is completed, the stack 300 carrying processed electronics structure 330′ can be debonded by placing the stack near a light source 350 (and/or moving the light source relative to the stack) to expose the carrier structure 310 to one or more pulses of debonding light generated by the light source. It will be appreciated that the light source 350 can have the same structure and operational characteristics of the light source 350 discussed above in connection with FIG. 1B. The stack 300 is positioned relative to the light source 350 so that the debonding light travels through a back side of the carrier body 312 (e.g., opposite the side the carrier structure 310 on which the bonding surface 316 is located) for absorption by the LAL 314. The light is absorbed by the LAL 314, resulting in heat generation in the LAL and heat transfer to the promotional sub-layer 324. The self-reacting, gas-generating promotional material heats and reacts with the adjacent adhesive material in the adhesive sub-layer 322 near the interface 326, resulting in foaming of the adhesive material and partial decomposition of the adhesive material in portions of the bonding layer 320 around the interface. As shown in FIG. 3C, the debonding reaction causes the bonding layer 320 to decompose substantially, leaving byproduct layers 322′ and 324′ on respective surfaces of the processed electronics structure 330′ and the carrier structure 310, respectively.

The foaming reaction in the present example provides several advantages to debonding, including providing an energetic debonding action around the interface 326 and increasing the surface area of residual material in the byproduct layers 322′ and 324′ after debonding to facilitate solution-based cleaning.

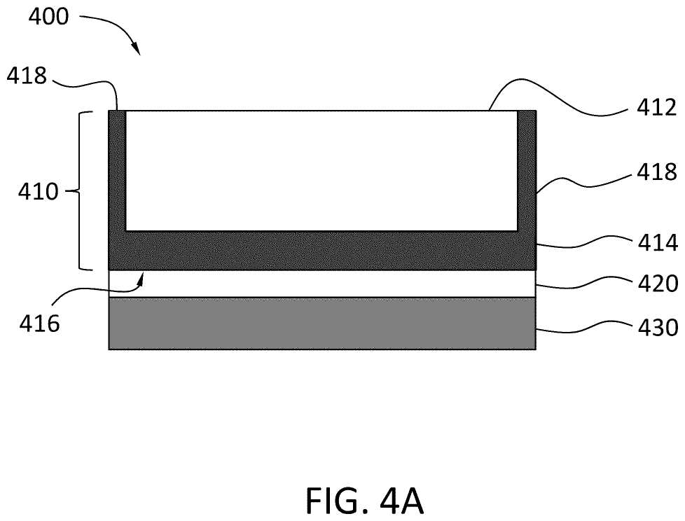

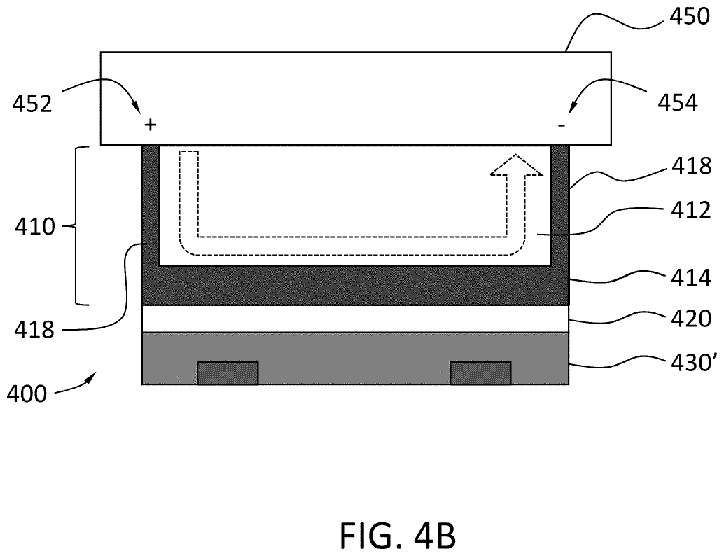

Referring now to FIGS. 4A-4B, an alternative example of a TBDB process using a reusable carrier structure, an electronics structure, and a bonding layer configured to vaporize substantially entirely during a debonding cycle is shown. In accordance with this example, a temporary stack for temporarily carrying an electronics structure for processing is shown generally as reference number 400 in FIG. 4A. The stack 400 includes a reusable carrier structure 410, a bonding layer 420, and an electronics structure 430. The reusable carrier structure 410 includes a carrier body 412 and a resistive electroconductive layer (ECL) 414 (broadly, a heat-generating layer) located on one side (e.g., a first side) of the carrier structure. An exposed surface of the ECL 414 defines a bonding surface 416 of the carrier structure 410. It will be appreciated that, in various other examples, other layers of material (e.g., a protective passivation layer and/or a layer comprising a low-surface-tension material, not shown) may be located outboard of the ECL 414 to define the bonding surface 416 without departing from the scope of the present disclosure. The carrier structure 410 additionally comprises two interconnects 418 configured to operatively connect the ECL 414 to an electricity source located away from the ECL (e.g., opposite the first side). The bonding layer 420 is configured to temporarily affix one side of the electronics structure 430 (e.g., a non-working side of the electronics structure) to the bonding surface 416 so the carrier structure 410 can be used to temporarily carry the electronics structure for one or more processing operations. It will be appreciated that the carrier body 412 can comprise a variety of rigid, thermally stable materials. The ECL 414 can comprise metal, metal alloys, semiconductors, ceramic, carbon, polymer, or other suitable materials with electrical conductivity.

It is contemplated that the carrier structure 410 can be used interchangeably with the LAL carrier structures 110, 210, 310 described above in connection with FIGS. 1A-1C, 2A-2D, and 3A-3C above, with the ECL 414 functioning as a heat-generating layer providing debonding heat to bonding layer 420. As can be seen in FIG. 4B, the carrier structure 410 can be operatively connected to a current-generating device 450 with a positive contact 452 and a negative contact 454. One or more pulses of current from the device 450 (broadly, pulses of debonding energy) travel through the ECL 414 via the interconnects 418, as indicated by the dashed arrow in FIG. 4B. As each pulse of current passes through the ECL 414, resistance in the ECL generates a corresponding amount of debonding heat. It is contemplated that the ECL can be configured to provide a substantially uniform heating profile (broadly, a substantially uniform energy distribution) over substantially all of the bonding surface 416 to facilitate even heating in the bonding layer 420. It is contemplated that the bonding layer 420 can be configured in accordance with the examples described above in connection with FIGS. 1A-1C, FIGS. 2A-2D, and/or FIGS. 3A-3C. It will be appreciated that other carrier structures with other kinds of heat-generating layers may be used without departing from the scope of the disclosure.

When introducing elements of the present disclosure or the preferred embodiments(s) thereof, the articles “a,” “an,” “the,” and “said” are intended to mean that there are one or more of the elements. The terms “comprising,” “including,” and “having” are intended to be inclusive and mean that there may be additional elements other than the listed elements.

As various changes could be made in the above constructions and methods without departing from the scope of the present disclosure, it is intended that all matter contained in the above description and shown in the accompanying drawings shall be interpreted as illustrative and not in a limiting sense. Although several examples of reusable carrier structures and features thereof are described above in connection with certain embodiments, it will be appreciated that numerous additions, combinations, and other modifications to the features described herein can be carried out without departing from the scope of the present disclosure. As a non-limiting example, it will be appreciated that multiple discrete light sources or current sources can be used to generate discrete debonding energy pulses rather than modulating a single light source or current source.

In view of the above, it will be seen that the several objects of the present disclosure are achieved and other advantageous results attained.

### Other Statements of the Disclosure

The following are statements or features of invention described in the present disclosure. Some or all of the following statements may not be currently presented as claims. Nevertheless, the statements are believed to be patentable and may subsequently be presented as claims. Associated methods corresponding to the statements or apparatuses below, and products and apparatuses corresponding to the methods below, are also believed to be patentable and may subsequently be presented as claims. It is understood that the following statements may refer to and be supported by one, more than one, or all the embodiments described above

A1. A temporary stack for temporarily carrying an electronics structure for processing, the temporary stack comprising:
a reusable carrier structure comprising a carrier body, the carrier structure defining a bonding surface on a first side of the carrier structure;
an electronics structure temporarily carried by the carrier structure on the first side; and a bonding layer configured to temporarily bond the electronics structure to the bonding surface;
wherein the temporary stack is configured to generate a debonding heat upon exposure to one or more pulses of debonding energy; and
wherein the bonding layer comprises one or more adhesive materials and is configured to vaporize substantially entirely upon exposure to the debonding heat.

A2. The temporary stack of statement A1, wherein the carrier structure comprises a heat-generating layer configured to generate the debonding heat upon exposure to the one or more pulses of debonding energy.

A3. The temporary stack of statement A2, wherein the heat-generating layer comprises a light-absorbing layer disposed on the carrier body on the first side.

A4. The temporary stack of statement A2, wherein the heat-generating layer comprises an electrically conductive layer disposed on the carrier body on the first side.

A5. The temporary stack of statement A1, wherein the bonding layer comprises an organic polymer.

A6. A photonic debonding system comprising a broadband, incoherent light source in combination with the temporary stack of statement A1.

A7. The photonic debonding system of statement A6, wherein the light source is configured to provide a substantially uniform heating profile in the bonding layer.

B1. A method of processing an electronics structure comprising:
providing a temporary stack comprising:
   a reusable carrier structure comprising a carrier body and a heat-generating layer carried by the carrier body on a first side of the carrier structure, the carrier structure defining a bonding surface on the first side;
   an electronics structure temporarily carried by the carrier structure on the first side; and
   a bonding layer configured to temporarily bond the electronics structure to the bonding surface, the bonding layer comprising at least one adhesive material and at least one promotional material,
providing at least one pulse of debonding energy to generate heat in the heat-generating layer to cause the promotional material to react to generate foam in the bonding layer and to weaken an adhesive strength of the adhesive material; and
separating the electronics structure from the carrier structure.

B2. The method of statement B1, wherein the providing at least one pulse of debonding energy comprises using a flashlamp configured to emit one or more pulses of incoherent broadband light.

B3. The method of statement B2, wherein the providing at least one pulse of debonding energy comprises modulating operating parameters of the flashlamp to emit at least a first pulse of light at a first energy level to activate the at least one promotional material and to emit at least a second pulse of light at a second energy level to weaken the at least one adhesive material.

C1. A system comprising:
A temporary stack for temporarily carrying an electronics structure for processing, the temporary stack comprising:
   a reusable carrier structure comprising a carrier body and a heat-generating layer carried on the carrier body, the carrier structure defining a bonding surface on a first side of the carrier structure;
   an electronics structure temporarily carried by the carrier structure on the first side; and
   a bonding layer configured to temporarily bond the electronics structure to the bonding surface, the bonding layer comprising at least one promotional material and at least one adhesive material; and
a debonding energy source configured to emit pulses of debonding energy;
wherein the heat-generating layer is configured to generate a debonding heat upon exposure to one or more pulses of debonding energy and transfer the debonding heat to the bonding layer; and
wherein the at least one promotional material and the at least one adhesive material are configured to react to form a foam byproduct when the at least one promotional material is exposed to the debonding heat.

C2. The system of statement C1, wherein the debonding energy source comprises a light source.

C3. The system of statement C2, wherein the light source comprises a flashlamp configured to emit pulses of incoherent, broadband light.

C4. The system of statement C2, wherein the heat-generating layer is a light-absorbing layer.

C5. The system of statement C1, wherein the wherein the debonding energy source comprises a generator of electrical energy.

C6. The system of statement C5, wherein the heat-generating layer comprises a layer of resistive, electroconductive material.

D1. A method of supplying a temporary stack for temporarily carrying an electronics structure for processing comprising:
applying at least one promotional material to a first surface of a carrier structure;
applying at least one adhesive material on top of the at least one promotional material opposite the first surface; and
applying an electronics structure on top of the at least one adhesive material.

D2. The method of statement D1, further comprising thermocompression bonding the at least one promotional material and the at least one adhesive material.

D3. The method of statement D1 comprising, prior to applying the at least one adhesive, permitting the at least one promotional material to cure.

D4. The method of statement D1 comprising, prior to applying the adhesive, permitting solvent to evaporate from the at least one promotional material.

D5. The method of statement D1, wherein applying the at least one promotional material comprises spin-coating the at least one promotional material.

D6. The method of statement D1, wherein applying the at least one adhesive material comprises spin-coating the at least one adhesive material.

E1. A method of manufacturing electronics structures, the method comprising:
providing a temporarily bonded stack; and
debonding the temporarily bonded stack for separating an electronics structure of the temporarily bonded stack from a carrier of the temporarily bonded stack, said debonding comprising:
   transmitting one or more pulses of energy to a heat generating layer of the temporarily bonded stack to generate debonding heat;
   transferring said debonding heat to a bonding layer of the temporary bonded stack; and
   permitting a promotional material of the bonding layer to react with an adhesive material of the bonding layer to form a foam byproduct to facilitate separating the electronics structure from the carrier.

What is claimed is:

1. A temporary stack for temporarily carrying an electronics structure for processing, the temporary stack comprising:
a reusable carrier structure comprising a carrier body and a heat-generating layer carried by the carrier body, the carrier structure defining a bonding surface on a first side of the carrier structure;
an electronics structure temporarily carried by the carrier structure on the first side; and
a bonding layer configured to temporarily bond the electronics structure to the bonding surface, the bonding layer comprising at least one promotional material and at least one adhesive material;
wherein the heat-generating layer is configured to generate a debonding heat upon exposure to one or more pulses of debonding energy and transfer the debonding heat to the bonding layer; and
wherein the at least one promotional material and the at least one adhesive material are configured to react to form a foam byproduct when the at least one promotional material is exposed to the debonding heat.

2. The temporary stack of claim 1, wherein the heat-generating layer comprises a light-absorbing layer disposed on the carrier body on the first side.

3. The temporary stack of claim 1, wherein the heat-generating layer comprises an electrically conductive layer disposed on the carrier body on at least the the first side.

4. The temporary stack of claim 1:
wherein the bonding layer comprises a promotional sub-layer comprising the at least one promotional material and an adhesive sub-layer comprising the at least one adhesive material;
wherein the promotional sub-layer and the adhesive sub-layer define an interface therebetween; and
wherein the promotional layer generates heat and gas upon exposure to the debonding heat to facilitate the formation of the foam byproduct around the interface.

5. The temporary stack of claim 1, wherein the at least one adhesive material comprises an organic polymer.

6. The temporary stack of claim 1, wherein the at least one promotional material comprises nitrocellulose.

7. The temporary stack of claim 1, wherein the at least one promotional material and the at least one adhesive material are soluble in a common solvent.

8. The photonic debonding system of claim 6, wherein the common solvent comprises alcohol.

9. A method of processing an electronics structure comprising:
providing a temporary stack comprising:
a reusable carrier structure comprising a carrier body and a heat-generating layer carried by the carrier body on a first side of the carrier structure, the carrier structure defining a bonding surface on the first side;
an electronics structure temporarily carried by the carrier structure on the first side; and
a bonding layer configured to temporarily bond the electronics structure to the bonding surface, the bonding layer comprising at least one adhesive material and at least one gas-generating material, each one of the at least one gas-generating material having a respective gasification temperature that is lower than a respective gasification temperature of each one of the at least one adhesive material;
exposing the heat-generating layer to one or more pulses of debonding energy that cause the at least one gas-generating material to generate gas; and
separating the electronics structure from the carrier structure after the gas is generated.

10. The method of claim 9, wherein the one or more pulses of debonding energy comprises a first pulse and a second pulse, and wherein one or more pulse parameters is modulated for each respective pulse to generate a different amount of debonding energy for each respective pulse.

11. The method of claim 10, wherein the first pulse is configured to generate debonding energy to cause one or more of the at least one gas-generating material to generate the gas.

12. The method of claim 11, wherein the second pulse is configured to generate debonding energy to cause one or more of the at least one adhesive material to weaken.

13. A temporary stack for temporarily carrying an electronics structure for processing, the temporary stack comprising:
a reusable carrier structure comprising a carrier body and a heat-generating layer carried on the carrier body on a first side of the carrier structure, the carrier structure defining a bonding surface on the first side;
an electronics structure temporarily carried by the carrier structure on the first side; and
a bonding layer configured to temporarily bond the electronics structure to the bonding surface;
wherein the heat-generating layer is configured to generate a debonding heat upon exposure to one or more pulses of debonding energy;
wherein the bonding layer comprises at least one adhesive material and at least one gas-generating material configured to generate gas upon exposure to the debonding heat; and
wherein the carrier is configured to transfer heat across the bonding surface and into the bonding layer with a substantially uniform energy distribution.

14. The temporary stack of claim 13, wherein the heat-generating layer comprises a light-absorbing layer.

15. The temporary stack of claim 13, wherein the heat-generating layer comprises an electrically conductive layer.

16. The temporary stack of claim 13, wherein the at least one gas-generating material comprises a low-order explosive.

17. The temporary stack of claim 13, wherein the at least one gas-generating material comprises two or more binary reactive materials.

18. The temporary stack of claim 17, wherein a pair of the two or more binary reactive materials comprises a reducer-oxidizer pair.

19. The temporary stack of claim 13, wherein each one of the at least one gas-generating material has a respective gasification temperature that is lower than a respective gasification temperature of each one of the at least one adhesive material.

20. The temporary stack of claim 19, wherein the bonding layer comprises a plurality of gas-generating materials each having a different respective gasification temperature relative to each other.
